(19) United States
(12) Patent Application Publication
(10) Pub. No.: US 2025/0321493 A1
(43) Pub. Date: Oct. 16, 2025

(54) METHOD FOR MANUFACTURING A MICRO-NANOMETRIC HIERARCHICAL STRUCTURE AND MICRO-NANOMETRIC HIERARCHICAL STRUCTURE OBTAINED BY SUCH A METHOD

(71) Applicants: STMicroelectronics International N.V., Geneva (CH); COMMISSARIAT A L'ENERGIE ATOMIQUE ET AUX ENERGIES ALTERNATIVES, Paris (FR)

(72) Inventors: Gaby BELOT, Saint Martin d'Hères (FR); Api WARSONO, Grenoble (FR); Ujwol PALANCHOKE, Grenoble (FR); Sebastien BERARD BERGERY, Grenoble (FR); Stefan LANDIS, Grenoble (FR); Remi COQUAND, Grenoble (FR)

(73) Assignees: STMicroelectronics International N.V., Geneva (CH); COMMISSARIAT A L'ENERGIE ATOMIQUE ET AUX ENERGIES ALTERNATIVES, Paris (FR)

(21) Appl. No.: 19/097,428

(22) Filed: Apr. 1, 2025

(30) Foreign Application Priority Data
Apr. 11, 2024 (FR) FR2403748

(51) Int. Cl. G03F 7/00; B82Y 40/00

(52) U.S. Cl. CPC G03F 7/70066; B82Y 40/00; G03F 7/70083; G03F 7/70416

(57) ABSTRACT

The present description concerns a manufacturing method comprising the exposure of a resist layer to a radiation by an optical lithography system comprising a mask, the mask comprising an array of pads opaque to radiation, spaced apart by a pitch, and distributed in at least two regions, the area ratios of the two regions being different, the pitch being equal, to within 10%, to the minimum resolution dimension of the Rayleigh criterion, and the development of the layer obtaining two pillars of different heights at the locations of the images of the two regions and of protrusions of nanometric heights at the top of each pillar at the locations of the images of the pillars.

### CROSS-REFERENCE TO RELATED APPLICATION(S)

This application claims the priority benefit of French patent application number 24/03748, filed on Nov. 4, 2024, entitled “Procédé de fabrication d'une structure hiérarchique micro-nanométrique et structure hiérarchique micro-nanométrique obtenu par un tel proceed”, which is hereby incorporated by reference to the maximum extent allowable by law.

### BACKGROUND

### Technical Field

The present disclosure generally concerns a method of manufacturing a micro-nanometric hierarchical structure, also called 2D hierarchical structure, comprising pillars of submicrometric, micrometric, or millimetric dimensions and protrusions of nanometric dimensions at the tops of the pillars.

### Description of the Related Art

Methods of manufacturing a 2D hierarchical structure generally comprise separate steps for the manufacturing of pillars having submicrometric, micrometric, or millimetric dimensions and for the manufacturing of protrusions having nanometric dimensions. An example of a method comprises the manufacturing of a mold comprising an impression of the pillars and protrusions, generally in a plurality of steps, and a step of nanoimprinting by pressing on a resin layer by using the mold or a step of injection molding by using the mold. Another example of a method comprises the successive forming of the pillars and of the protrusions in a layer by successive optical lithography and etch steps.

A disadvantage of such methods is that they comprise a large number of steps and are difficult to implement on an industrial scale.

### BRIEF SUMMARY

An embodiment is directed to overcomes all or part of the disadvantages of known methods of manufacturing a hierarchical micro-nanometric structure.

An embodiment provides a manufacturing method comprising the following successive steps:
exposure of a resist layer to an electromagnetic radiation by an optical lithography system comprising a mask crossed by the electromagnetic radiation, the mask comprising an array of pads opaque to the electromagnetic radiation, spaced apart by a pitch, and distributed in at least two regions of the mask, each region being defined by an area ratio between the area of the opaque pads of the region and the total area of the region, said area ratios of the two regions being different, the pitch being equal, to within 10%, to the minimum resolution dimension of the Rayleigh criterion; and
development of the layer, which results at least in the obtaining in the layer of two pillars of different heights at the locations of the images of the two regions and protrusions of nanometric heights at the top of each pillar at the locations of the images of the pads.

According to an embodiment, the optical lithography system comprises a source of electromagnetic radiation, and the minimum resolution dimension (of the Rayleigh criterion) is given by the following relation:

$${P}_{min} = \frac{1}{1 + σ} \cdot \frac{λ}{{NA}_{s}} \qquad [ Math 1 ]$$

where λ is the wavelength of the electromagnetic radiation, NAs is the numerical aperture on the image side of the optical lithography system, and σ is the partial coherence factor of the electromagnetic radiation source.

According to an embodiment, the resist is a low-contrast resist.

According to an embodiment, the pitch of the pads is constant across the entire mask.

According to an embodiment, each pad has a cross-section inscribed within a square, the dimensions of the side of the square for the pads of the two regions being different.

According to an embodiment, the difference in heights of the two pillars is in the range from 1 nm to the thickness of the layer, preferably from 50 nm to 2,000 nm.

According to an embodiment, the height of the protrusions is in the range from 0 nm to 200 nm, preferably from 40 nm to 100 nm.

According to an embodiment, the height of the protrusions depends on the duration of the step of development of the layer.

According to an embodiment, the resin layer rests on a substrate, the method further comprising a step of anisotropic etching of the resin layer and of the substrate, which results in the transferring of the shape of the pillars and of the protrusions into the substrate.

According to an embodiment, the top of each pillar has an area greater than 1 μm².

An embodiment also provides a structure comprising a resist layer comprising at least two pillars of different heights and protrusions of nanometric heights at the top of each pillar.

### BRIEF DESCRIPTION OF THE SEVERAL VIEWS OF THE DRAWINGS

The foregoing features and advantages, as well as others, will be described in detail in the rest of the disclosure of specific embodiments given as an illustration and not limitation with reference to the accompanying drawings, in which:

FIG. 1 is a perspective view, partial and simplified, of an embodiment of a 2D hierarchical structure;

FIG. 2 is a side view, partial and simplified, of the 2D hierarchical structure of FIG. 1;

FIG. 3 is a cross-section view, partial and simplified, of an optical lithography system;

FIG. 4 and FIG. 5 are top views, partial and simplified, of embodiments of the mask used of the optical lithography system of FIG. 3;

FIG. 6 shows resist contrast curves;

FIG. 7A, FIG. 7B, and FIG. 7C are side views, partial and simplified, of structures obtained at successive steps of an embodiment of a method of manufacturing the 2D hierarchical structure of FIG. 1;

FIG. 8 is a side view, partial and simplified, of the structure obtained at a step of another embodiment of a method of manufacturing the 2D hierarchical structure of FIG. 1;

FIG. 9 is a perspective view, partial and simplified, of a 2D hierarchical structure obtained by simulation;

FIG. 10 is a curve of the variation of the profile of the 2D hierarchical structure of FIG. 9 along a measurement line at a first measurement scale;

FIG. 11 is a curve of the variation of the profile of the 2D hierarchical structure of FIG. 9 along the measurement line at a second measurement scale;

FIG. 12 shows the height of pillars manufactured by using masks having different densities of opaque pads and different pitches between opaque pads;

FIG. 13, FIG. 14, and FIG. 15 are images, obtained by atomic force microscopy, of the upper surface of pillars manufactured by using masks having opaque pads of different sizes; and

FIG. 16 is a curve of the variation of the profile of the pads on the upper surface of a pillar of FIG. 14 along a measurement line.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

The transmittance of a layer corresponds to the ratio of the intensity of the radiation coming out of the layer to the intensity of the radiation entering the layer, the rays of the incoming radiation being perpendicular to the layer. In the rest of the disclosure, a layer or a film is said to be opaque to a radiation when the transmittance of the radiation through the layer or the film is lower than 10%. In the rest of the disclosure, a layer or a film is said to be transparent to a radiation when the transmittance of the radiation through the layer or the film is higher than 60%.

In addition, the terms “insulating” and “conductive” respectively signify “electrically insulating” and “electrically conductive”.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10% or 10°, preferably of plus or minus 5% or 5°.

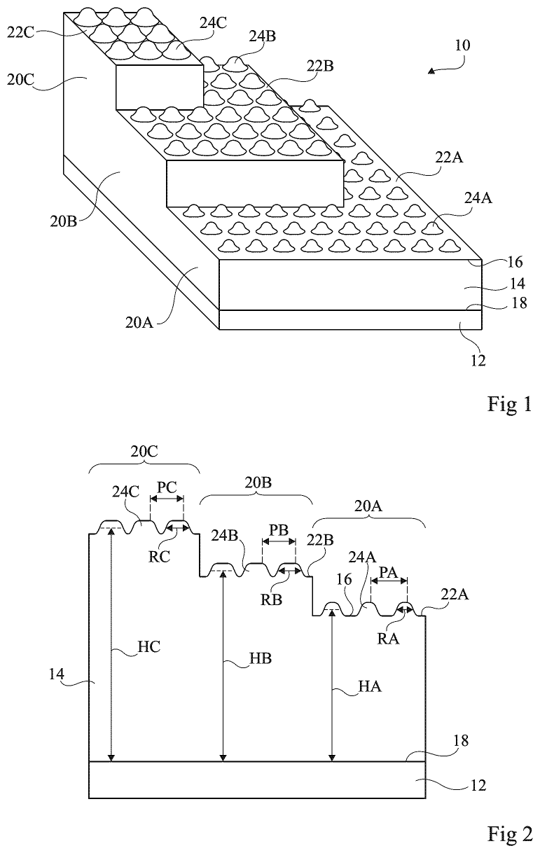

FIG. 1 is a perspective view, partial and simplified, of an embodiment of a 2D hierarchical structure 10, and FIG. 2 is a side view, partial and simplified, of the 2D hierarchical structure 10 of FIG. 1.

2D hierarchical structure 10 comprises a substrate 12 and a layer 14 covering substrate 12 and having an upper surface 16, on the side opposite to substrate 12, and a lower surface 18, on the side of substrate 12 opposite to upper surface 16. According to an embodiment, lower surface 18 is planar.

2D hierarchical structure 10 comprises pillars 20A, 20B, 20C of different heights, the height being measured from lower surface 18. As an example, in FIGS. 1 and 2, 2D hierarchical structure 10 comprises a pillar 20A of average height HA, a pillar 20B of average height HB, greater than average height HA, and a pillar 20C of average height HC greater than height HB. However, it is clear that 2D hierarchical structure 10 may comprise more than one pillar 20A of average height HA, more than one pillar 20B of average height HB, and/or more than one pillar 20C of average height HC. Further, 2D hierarchical structure 10 may only comprise pillars of two different heights, or pillars having different heights from among more than three different heights. The flanks of pillars 20A, 20B, 20C may be substantially orthogonal to lower surface 18 or more or less inclined with respect to a direction perpendicular to lower surface 18.

Generally, the average height of two pillars is not identical to within one nanometer. According to an embodiment, the difference in heights HA, HB, HC between two pillars 20A, 20B, 20C is in the range from 1 nm to the thickness of layer 14, preferably from 50 nm to 2,000 nm. According to an embodiment, average height HA is in the range from 50 nm to 500 nm. According to an embodiment, average height HB is in the range from 550 nm to 1,000 nm. According to an embodiment, average height HC is in the range from 1,050 nm to 1,500 nm.

Each pillar 20A, 20B, 20C comprises an upper surface 22A, 22B, 22C on the side opposite to substrate 12. According to an embodiment, the upper surface 22A, 22B, 22C of each pillar 20A, 20B, 20C, viewed in a direction orthogonal to lower surface 18, has an area greater than 1 μm².

The upper surface 22A, 22B, 22C of each pillar 20A, 20B, 20C comprises an array of protrusions 24A, 24B, 24C. According to an embodiment, the height of each protrusion 24A, 24B, 24C is in the range from 0 to 200 nm, preferably from 40 nm to 100 nm, a height of protrusion 24A, 24B, 24C equal to 0 corresponding to a substantially planar upper surface 22A, 22B, 22C. Protrusions 24A, 24B, 24C are arranged in rows and in columns. The pitch PA, PB, PC of the array of protrusions 24A, 24B, 24C is the distance between the axis of a protrusion 24A, 24B, 24C to the axis of the nearest protrusion 24A, 24B, 24C in the same row or in an adjacent row. According to an embodiment, pitch PA is substantially the same for all the protrusions 24A resting on each pillar 20A, pitch PB is substantially the same for all the protrusions 24B resting on each pillar 20B, and pitch PC is substantially the same for all the protrusions 24C resting on each pillar 20C. According to an embodiment, each pitch PA, PB, PC is in the range from 330 nm to 410 nm. According to an embodiment, pitches PA, PB, and PC are substantially identical.

There is called RA, RB, RC the radius of the circle having the cross-section of protrusion 24A, 24B, 24C at mid-height of protrusion 24A, 24B, 24C inscribed therein. According to an embodiment, radius RA, RB, RC is in the range from 100 nm to the corresponding pitch PA, PB, PC decreased by 40 nm. According to an embodiment, the radii RA, RB, and RC of protrusions 24A, 24B, 24C are identical. According to an embodiment, the radius RA of protrusions 24A is smaller than the radius RB of protrusions 24B, and the radius RB of protrusions 24B is smaller than the radius RC of protrusions 24C.

Protrusions 24A, 24B, 24C may be arranged in a square mesh, as shown in FIG. 1. In this arrangement, a protrusion 24A, 24B, 24C is located at each intersection of a row and of a column, the rows being perpendicular to the columns. As a variant, protrusions 24A, 24B, 24C may be arranged in a hexagonal mesh. In this arrangement, the protrusions 24A, 24B, 24C on a row are offset by half pitch PA, PB, PC relative to the protrusions on the previous row and on the next row.

According to an embodiment, layer 14 is made of resist. The resist is a resin adapted to the implementation of an optical grayscale lithography method, known as a grayscale resist. According to an embodiment, layer 14 is made of hydrogen silsesquioxane, or poly(silsesquioxane).

According to an embodiment, layer 14 is made of a material different from a resist, for example, of a semiconductor material, for example, of silicon, or of an insulating material, for example of silicon oxide or of silicon nitride. In this case, as described in further detail hereafter, the forming of 2D hierarchical structure 10 is obtained by a pattern transfer method.

An example of the application of 2D hierarchical structure 10 is the obtaining of a surface having a variable and controlled wettability.

Methods of forming reliefs in a resist layer comprise optical lithography methods which comprise an exposure step in which the resin layer is exposed to an electromagnetic radiation through a mask, followed by a development step in which the resin layer is immersed in a development solution, the portions of the resin layer exposed in the case of a positive resist, or the portions of the resin layer not exposed in the case of a negative resist, being dissolved in the development solution.

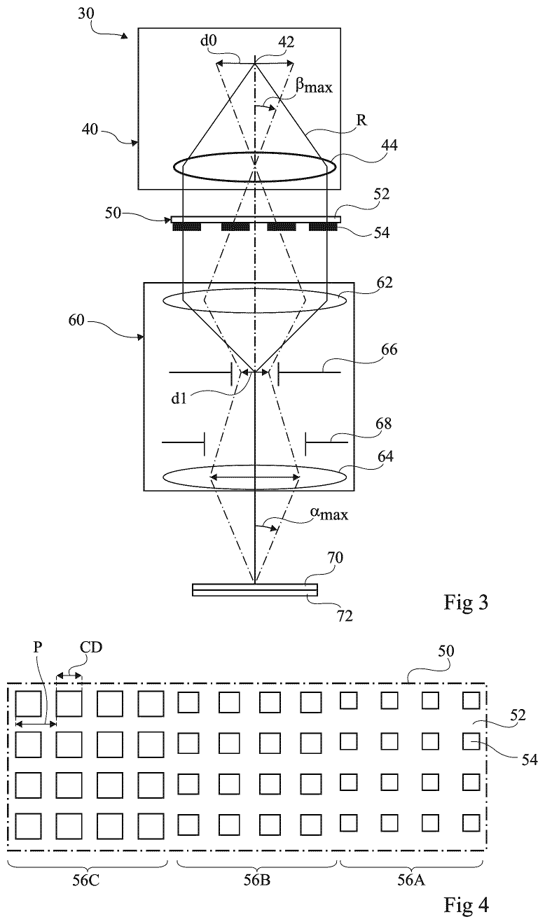

FIG. 3 shows, partially and schematically, an embodiment of an optical lithography system 30.

In the embodiment illustrated in FIGS. 1 and 2, each pillar 20A, 20B, 20C is shown as adjacent, that is, in contact with at least another pillar. According to another embodiment, at least one of pillars 20A, 20B, 20C may be separated from another pillar by a groove, extending in layer 14 over part or all of the height of layer 14.

According to an embodiment, optical lithography system 30 comprises four distinct elements: an illumination system 40, a mask 50, an optical projection system 60, and a resin layer 70 deposited on a substrate 72. Illumination system 40 emits a monochromatic exposure radiation R of wavelength λ, which is diffracted as it crosses mask 50. Optical projection system 60 enables to collect the diffracted radiation to restore the image of mask 50 on resin layer 70.

According to an embodiment, illumination system 40 comprises a monochromatic source 42 of the radiation R of wavelength λ and a condenser 44. Source 42 comprises, for example, an excimer laser based on an argon-fluorine (ArF) mixture. Condenser 44 comprises an assembly of lenses, mirrors, and other optical elements having the role of collecting and of filtering the radiation R originating from source 42. As an example, source 42 is arranged at the object focal plane of condenser 44. Thus, each source point generates a planar wave on mask 50. This configuration enables to obtain a uniform illumination over the entire mask 50.

Optical projection system 60 comprises a plurality of lenses (two lenses 62, 64 being shown as an example in FIG. 3) operating in transmission mode and comprises an entrance pupil 66 and an exit pupil 68. Optical projection system 60 enables to collect the radiation diffracted by mask 50 and to project it onto resin layer 70, possibly with a reduction factor M for example equal to 4 or 5. The advantage of having a reduction factor M greater than 1 is that it is no longer necessary to have the patterns of mask 50 of the same size as the patterns to be printed. This releases constraints on the manufacturing of mask 50.

The numerical aperture NAₛ of optical projection system 60 corresponds to the numerical aperture on the image side of optical projection system 60 and describes the ability of the system to collect the diffracted radiation originating from mask 50 and which takes part in the forming of the image at resin layer 70. Numerical aperture NAₛ is defined by the following equation Math 2:

$${NA}_{s} = n \cdot sin ( {α}_{max} ) \qquad [ Math 2 ]$$

where n is the index of the medium between the output of optical projection system 60 and resin layer 70, generally air, and αₘₐₓ is the maximum half-angle of the cone of the radiation incident on resin layer 70.

The lenses 62, 64 of optical projection system 60 are arranged so that the image of source 42 through the optical elements of illumination system 40 is in the entrance pupil 66 of optical projection system 60. However, the size d1 of the source 42 obtained in the plane of entrance pupil 66 is different from the initial size d0 of source 42. The ratio of the image size of source 42 obtained at entrance pupil 66 to the numerical aperture NAₑ of the entrance pupil is called partial coherence factor σ of source 42 and is given by the following equation Math 3:

$$σ = \frac{sin ( {β}_{max} )}{{NA}_{e}} \qquad [ Math 3 ]$$

where βₘₐₓ is the maximum half-angle of the cone of the radiation incident on condenser 44 and NAₑ is the numerical aperture on the object side of optical projection system 60.

The numerical aperture on the image side NAₛ and the numerical aperture on the object side NAₑ are linked to each other by reduction factor M. Thus, the partial coherence σ of the source may also be expressed as a function of the numerical aperture on the image side NAₛ according to the following relation Math 4:

$$σ = M \cdot \frac{sin ( {β}_{max} )}{{NA}_{s}} \qquad [ Math 4 ]$$

Generally, the partial coherence σ is in the range from 0 to 1.

Optical lithography system 30 is characterized by its limiting resolution. It corresponds to the smallest pitch of patterns of mask 50 that can be resolved in resin layer 70. It is known to use the Rayleigh criterion, which links the minimum pitch Pₘᵢₙ of mask 50 that can be resolved by optical lithography system 30 according to the following relation Math 5:

$${P}_{min} = \frac{1}{1 + σ} \cdot \frac{λ}{{NA}_{s}} \qquad [ Math 5 ]$$

According to an embodiment, ratio 1/(1+σ) is greater than 0.25.

There exist different types of optical lithography methods, including binary optical lithography methods and grayscale optical lithography methods.

In binary optical lithography processes, resin layer 70 is exposed across its entire thickness so that, after the development step, there remain resin pillars having the initial thickness of the resin layer separated by spaces where the resin layer has been removed across its entire thickness. The mask 50 used for the implementation of the binary optical lithography process generally is a mask called binary mask comprising a support 52 transparent to radiation and pillars 54 opaque to radiation.

In grayscale optical lithography methods, resin layer 70 may be exposed across only part of its thickness, so that, after the development stage, resin pillars of varied thicknesses can be obtained.

The optical grayscale lithography method may use a mask 50 more or less transparent to radiation, to locally vary the exposure dose received by resin layer 70. The mask 50 used for the optical grayscale lithography method may also be a binary mask.

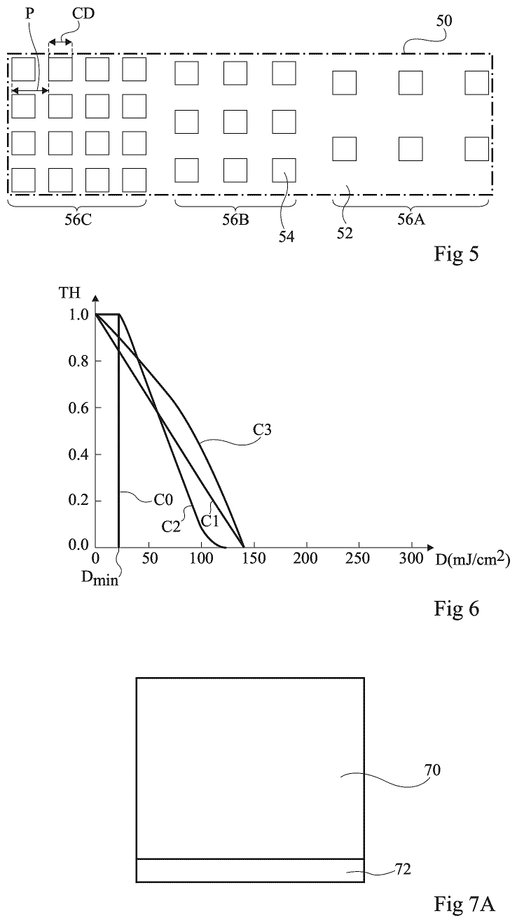

FIG. 4 and FIG. 5 are top views, partial and simplified, of embodiments of binary mask 50. Mask 50 comprises a support 52 transparent to radiation having pads 54 transparent to radiation resting thereon. As a variation, opaque pads 54 are embedded in transparent support 52. There is called FF ratio of a region of mask 50, in the view of FIG. 4 or 5, the ratio of the area occupied by opaque pads 54 to the total area of the region. The higher the FF ratio, the more a portion of the considered region is opaque to the radiation used during the exposure step. The pitch P of opaque pads 54 corresponds to the distance between a center of an opaque pad 54 and the center of an adjacent opaque pad. In the view of FIGS. 4 and 5, each opaque pad 54 corresponds to a square, and there is called CD the measurement of the side length of the square. Generally, opaque pads 54 may have a shape different from a square, for example the shape of a pentagon, for example a rectangle, a circle, or an ellipse. There is then called CD the measurement of the side length of the square having opaque pad 54 inscribed therein.

In a binary optical lithography process, the pitch P between opaque pads 54 is significantly greater than the minimum pitch Pₘᵢₙ, indicated by relation Math 5, that can be resolved by optical lithography system 30, so that the image of each opaque pad 54 is copied in resin layer 70, and resin layer 70 is only exposed to radiation between the image of each opaque pad 54 of mask 50.

In an optical grayscale lithography method, the pitch between opaque pads 54 is significantly smaller than the minimum pitch Pₘᵢₙ that can be resolved by optical lithography system 30. Opaque pads 54 are not resolved on resin layer 70. Mask 50 then behaves as if it had a local transmittance to radiation which depends on the local FF ratio. Opaque pads 54 are then arranged to vary the FF ratio on mask 50 so that the radiation dose reaching resin layer 70 varies locally.

According to an embodiment, a method of manufacturing a 2D hierarchical structure comprises using a resist adapted to the implementation of an optical gray-scale lithography method, the use of a binary mask, and the implementation of a step of exposure of the resist under conditions different from an optical grayscale lithography and optical binary lithography method.

Indeed, the pitch P of opaque pads 54 is selected to be equal, to within 10%, to the minimum pitch Pₘᵢₙ indicated by relation Math 5. The inventors have shown that, under these conditions, effects specific to binary optical lithography methods and to grayscale optical lithography methods can be obtained.

According to an embodiment illustrated in FIG. 4 and in FIG. 5, mask 50 comprises regions 56A, 56B, 56C in which the FF ratios are different. As an example, a single region 56A, a single region 56B, and a single region 56C are shown as an example in FIGS. 4 and 5. The FF ratio of region 56A, referred to as the low FF ratio hereafter, is lower than the FF ratio of region 56B, referred to as the intermediate FF ratio hereafter, and the FF ratio of region 56B is lower than the FFC ratio of region 56C, referred to as the high FF ratio hereafter.

The inventors have shown that, when the pitch P of opaque pads 54 is equal, to within 10%, to the minimum pitch Pₘᵢₙ indicated by relation Math 5, after the development step, resin layer 70 has the structure of layer 14 of the 2D hierarchical structure 10 of FIG. 1. More precisely, the inventors have shown that one obtains in resin layer 70 after the development step:
a pillar 20A for each region 56A having dimensions corresponding to the image of the corresponding region 56A, a pillar 20B for each region 56B having dimensions corresponding to the image of the corresponding region 56B, and a pillar 20C for each region 56C having dimensions corresponding to the image of the corresponding region 56C; and
protrusions 24A, 24B, 24C at the top of each pillar 20A, 20B, 20C, the position of protrusions 24A, 24B, 24C corresponding to the images of the opaque pads 54 of mask 50.

According to an embodiment, the height of protrusions 24A, 24B, 24C depends on the duration of the development step.

In the embodiment illustrated in FIG. 4, the pitch P between opaque pads 54 is identical for regions 56A, 56B, 56C and the dimensions CD of opaque pads 54 are different between regions 56A, 56B, 56C. The dimension CD for region 56C is greater than the dimension CD for region 56B, and the dimension CD for region 56B is greater than the dimension CD for region 56A.

According to an embodiment, the wavelength λ of the exposure radiation R is equal to approximately 365 nm. According to an embodiment, the numerical aperture on the image side NAₛ is in the range from 0.4 to 1.0. According to an embodiment, the pitch P of opaque pads 54 is in the range from 300 nm to 420 nm for an exposure wavelength λ equal to approximately 365 nm.

Resists adapted to binary optical lithography are called high-contrast resists or binary resists. Resists adapted to grayscale optical lithography are called low-contrast resists or grayscale resists.

FIG. 6 shows curves of the variation of the normalized remaining thickness TH of a positive resist layer as a function of the dose D of exposure radiation received by the resist layer for an ideal binary resist (curve C0), an ideal grayscale resist (curve C1), a real binary resist (curve C2), and a real grayscale resist (curve C3). Such curves are also known as contrast curves. The normalized remaining thickness TH is equal to the ratio of the thickness of the resist layer after the exposure and development steps to the initial thickness of the resist layer.

An ideal binary resist (curve C0) exhibits an inhibition at low doses, that is, the solubility of the resist in the development solution is zero when the dose is below a dose threshold Dₘᵢₙ and only increases when the dose is higher than dose threshold Dₘᵢₙ. This means that the remaining thickness of the exposed resist layer is equal to the initial thickness when the dose is lower than dose threshold Dₘᵢₙ. Above dose threshold Dₘᵢₙ, all the ideal binary resist is dissolved in the development solution, which corresponds to the remaining thickness TH substantially equal to zero after the development step. For a real binary resist (curve C2), beyond the dose threshold, a very abrupt decrease of the remaining thickness, but not almost infinite, can be observed, the remaining thickness TH however depending on the exposure dose according to a non-linear relation.

For an ideal grayscale resist (curve C1), the relation between the remaining thickness TH and the exposure dose D is substantially linear, with a moderate slope. Further, there is substantially no inhibition at low doses, that is, the remaining thickness TH of the resist layer decreases as soon as dose D is greater than zero. For an ideal grayscale resist (curve C3), the relation between the remaining thickness TH and exposure dose D is not perfectly linear, but the inhibition at low doses remains very low, and is preferably zero.

According to an embodiment, the inhibition at low doses of the resist is lower than 5 mJ/cm². According to an embodiment, the resist does not totally dissolve in the development solution when the dose is lower than 120 mJ/cm² and the resist totally dissolves in the development solution when the dose is higher than 300 mJ/cm².

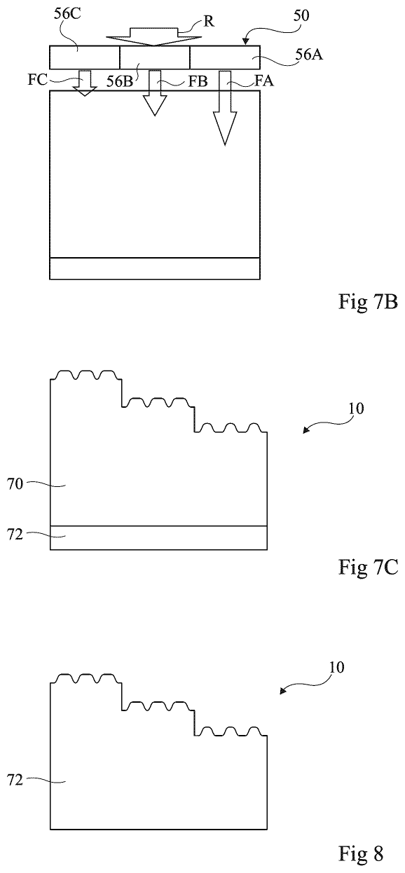

FIG. 7A, FIG. 7B, and FIG. 7C are side views, partial and simplified, of structures obtained at successive steps of an embodiment of an embodiment of a method of manufacturing for the 2D hierarchical structure 10 of FIG. 1, in the case where layer 14 is made of resist.

FIG. 7A illustrates the structure obtained after the forming of layer 70 on substrate 72. According to an embodiment, the initial thickness of resin layer 70 is in the range from 500 nm to 2,000 nm. According to an embodiment, resin layer 70 is deposited by a spin-coating method. Layer 70 is made of a low-contrast resist adapted to the implementation of an optical gray-scale lithography method.

FIG. 7B illustrates the structure obtained during the exposure of layer 70 to exposure radiation R through binary mask 50. The opaque pads 54 of mask 50 are arranged so that the pitch P between the opaque pads is equal, to within 10%, to the minimum pitch Pₘᵢₙ indicated by relation Math 5. According to an embodiment, mask 50 has the structure shown in FIG. 4 or 5. According to an embodiment, the pitch P of opaque pads 54 is in the range from 300 nm to 420 nm for a wavelength λ substantially equal to 365 nm. According to an embodiment, the wavelength of exposure radiation R is in the range from 365 nm to 420 nm. In FIG. 7B, regions 56A, 56B, and 56C of mask 50 have been schematically shown, and there has been illustrated by arrows FA, FB, and FC of different sizes that the dose of exposure radiation R crossing region 56A is higher than the dose of exposure radiation R crossing region 56B and that the dose of exposure radiation R crossing region 56B is higher than the dose of exposure radiation R crossing region 56C.

FIG. 7C illustrates the structure obtained after a step of development of layer 70, in which the portions of layer 70 that have been exposed to exposure radiation through mask 50 are removed by soaking layer 70 in a development solution. The 2D hierarchical structure 10 of FIG. 1 is then obtained, the resist layer 70 in FIG. 7C after development corresponding to the layer 14 of FIG. 1 and substrate 72 corresponds to the substrate 12 of FIG. 1. According to an embodiment, the development step comprises the placing into contact of resist layer 70 in a solution, for example a tetramethylammonium hydroxide (TMAH) solution or a sodium hydroxide solution.

An advantage of the embodiment of the previously-described manufacturing method is that pillars 20A, 20B, and 20C and pads 24A, 24B, 24C are formed simultaneously. Further, the dimensions of pillars 20A, 20B, and 20C and of pads 24A, 24B, 24C may be precisely and reproducibly obtained by the control of the exposure conditions. The method may easily be implemented on an industrial scale.

FIG. 8 is a side view, partial and simplified, of the structure obtained at a step of another embodiment of a method of manufacturing the 2D hierarchical structure 10 of FIG. 1, in the case where layer 14 is not made of resist.

According to this embodiment, the method comprises the steps previously described in relation with steps 7A to 7C and further comprises a step of transfer into substrate 72 of the patterns formed in resin layer 70 by an anisotropic etch step. The substrate 72 obtained after the etch step corresponds to the layer 14 in FIG. 1.

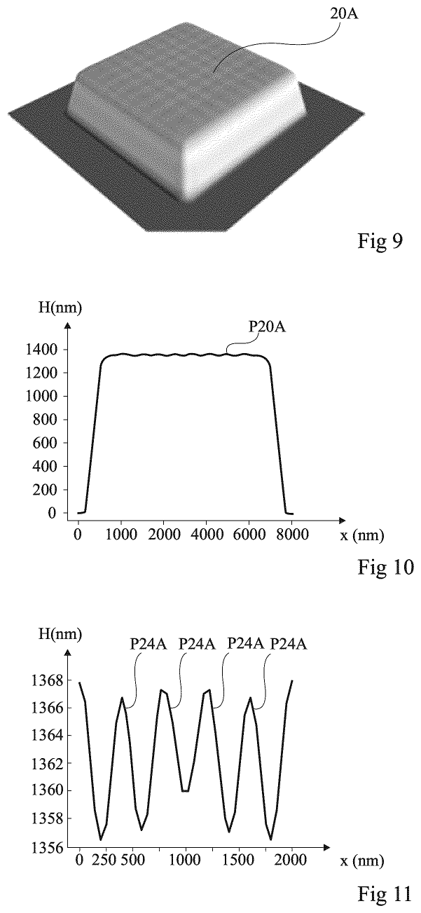

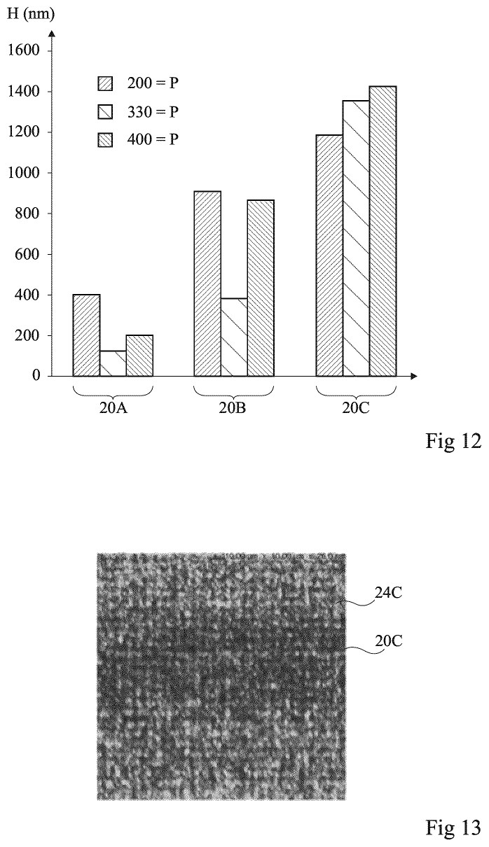

FIG. 9 is a perspective view, partial and simplified, of a 2D hierarchical structure obtained by simulation, comprising a single pillar 20A.

FIG. 10 is a curve of the variation of the height H of the 2D hierarchical structure along a measurement line x at a first measurement scale. The profile of FIG. 10 comprises a plateau P20A, which indicates the forming of pillar 20A.

FIG. 11 is a curve of the variation of the profile H of the 2D hierarchical structure of FIG. 9 along measurement line x at a second measurement scale. The profile of FIG. 11 comprises peaks P24A, which indicates the forming of protrusions 24A.

Three tests have been carried out by using masks 50, each having a constant pitch P across the entire mask 50. For these tests, the minimum pitch Pₘᵢₙ of mask 50 that can be resolved by the optical lithography system 30 according to relation Math 5 is equal to 376 nm. The first test is performed by using a mask 50 with a pitch P equal to 200 nm. The second test is performed by using a mask 50 with a pitch P equal to 300 nm. The third test is performed by using a mask 50 with a pitch P equal to 400 nm. For each test, mask 50 comprises a region 56A with the low FF ratio, a region 56B with the intermediate FF ratio, and a region 56C with the high FF ratio. Pillars 20A, 20B, and 20C of different heights have been obtained.

FIG. 13, FIG. 14, and FIG. 15 are images, obtained by atomic force microscopy, of the upper surface respectively of a pillar 20C, of a pillar 20B, and of a pillar 20A, obtained with a mask 50 having a constant P pitch across the entire mask 50 equal to 400 nm, respectively. FIG. 13 is an image of the upper surface of pillar 20C, the distance CD of opaque pads 54 from the corresponding region 56C of mask 50 being equal to 360 nm. FIG. 14 is an image of the upper surface of pillar 20B, the distance CD of the opaque pads 54 of the corresponding region 56B of mask 50 being equal to 280 nm. FIG. 15 is an image of the upper surface of pillar 20A, the distance CD of the opaque pads 54 of the corresponding region 56A of mask 50 being equal to 222 nm.

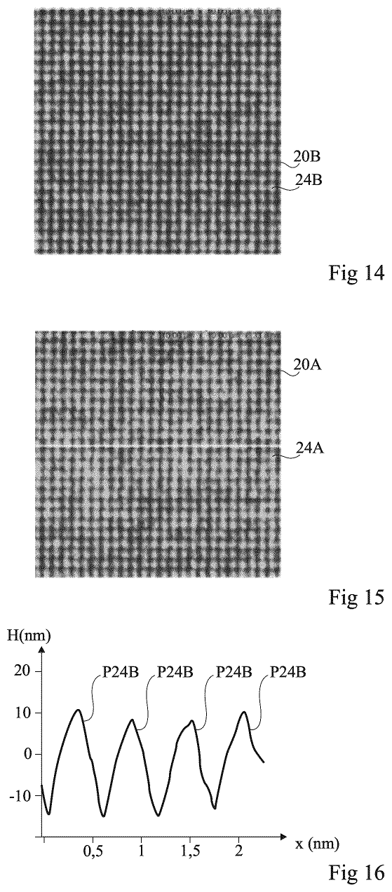

FIG. 16 shows a curve of the profile H of the upper surface of the pillar 20B of FIG. 14 along a measurement line x. The profile of FIG. 16 comprises peaks P24B, which indicates the forming of protrusions 24B. Protrusions 24B have a maximum height in the order of from 25 nm to 30 nm.

According to an embodiment, the height of each protrusion 24A, 24B, 24C is in the range from 30 nm to 100 nm, inclusive.

Each protrusion 24A, 24B, 24C has a top. The tops of the protrusions 24A on the pillar 20A are in a first plane. The tops of the protrusions 24B on the pillar 20B are in a second plane. The tops of the protrusions 24C on the pillar 20C are in a third plane. According to an embodiment, the first, second, and the third planes are distant from each other.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

Manufacturing method is summarized as including the following steps: exposure of a resist layer (70) to an electromagnetic radiation (R) by an optical lithography system (30) including a mask (50) crossed by the electromagnetic radiation (R), the mask (50) including an array of pads (54) opaque to the electromagnetic radiation (R), spaced apart by a pitch (P), and distributed in at least two regions (56A, 56B, 56C) of the mask (50), each region (56A, 56B, 56C) being defined by an area ratio between the area of the opaque pads (54) of the region and the total area of the region, said area ratios of the two regions (56A, 56B, 56C) being different, the pitch (P) being equal, to within 10%, to the minimum resolution dimension (Pₘᵢₙ) of the Rayleigh criterion; and development of the layer (70), which results at least in the obtaining in the layer of two pillars (20A, 20B, 20C) of different heights (HA, HB, HC) at the locations of the images of the two regions (56A, 56B, 56C) and of protrusions (24A, 24B, 24C) of nanometric heights at the top of each pillar (20A, 20B, 20C) at the locations of the images of the pads (54).

The optical lithography system (30) includes a source (42) of the electromagnetic radiation (R), and wherein the minimum resolution dimension (Pₘᵢₙ) of the Rayleigh criterion is given by the following relation:

$${P}_{min} = \frac{1}{1 + σ} \cdot \frac{λ}{{NA}_{s}} \qquad [ Math 6 ]$$

where λ is the wavelength of the electromagnetic radiation (R), NAₛ is the numerical aperture on the image side of the optical lithography system (30), and σ is the partial coherence factor of the source (42) of the electromagnetic radiation (R).

The resist is a low-contrast resist.

The pitch (P) of the pads (54) is constant across the entire mask (50).

Each pad (54) has a cross-section inscribed within a square, the dimensions (CD) of the side of the square for the pads (54) of the two regions (56A, 56B) being different.

The difference in heights (HA, HB, HC) of the two pillars (20A, 20B, 20C) is in the range from 1 nm to the thickness of the layer (70), preferably from 50 nm to 2,000 nm.

The height of the protrusions (24A, 24B, 24C) is in the range from 0 nm to 200 nm, preferably from 40 nm to 100 nm.

The height of the protrusions (24A, 24B, 24C) depends on the duration of the step of development of the layer (70).

The resin layer (70) rests on a substrate (72), the method further includes a step of anisotropic etching of the resin layer (70) and of the substrate (72), which results in the transferring of the shape of the pillars (20A, 20B, 20C) and of the protrusions (24A, 24B, 24C) into the substrate (72).

The top of each pillar (20A, 20B, 20C) has an area greater than 1 μm².

Structure is summarized as including a resist layer (70) including at least two pillars (20A, 20B, 20C) of different heights (HA, HB, HC) and protrusions (24A, 24B, 24C) of nanometric heights at the top of each pillar (20A, 20B, 20C).

The top of each pillar (20A, 20B, 20C) has an area greater than 1 μm².

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A manufacturing method comprising:
exposing of a resist layer to an electromagnetic radiation by an optical lithography system comprising a mask crossed by the electromagnetic radiation, the mask comprising an array of pads opaque to the electromagnetic radiation, spaced apart by a pitch, and distributed in at least two regions of the mask, each region being defined by an area ratio between the area of the opaque pads of the region and the total area of the region, the area ratios of the two regions being different, the pitch being within 10% of the minimum resolution dimension of the Rayleigh criterion; and
developing the resist layer, which results at least in obtaining in the layer of two pillars of different heights at locations of images of the two regions and of protrusions of nanometric heights at the top of each pillar at locations of images of the opaque pads.

2. The method according to claim 1, wherein the optical lithography system comprises a source of the electromagnetic radiation, and wherein the minimum resolution dimension of the Rayleigh criterion is given by the following relation:
$${P}_{min} = \frac{1}{1 + σ} \cdot \frac{λ}{{NA}_{s}}$$
where λ is the wavelength of the electromagnetic radiation, NAₛ is the numerical aperture on the image side of the optical lithography system, and σ is the partial coherence factor of the source of the electromagnetic radiation.

3. The method according to claim 1, wherein the resist of the resist layer is a low-contrast resist.

4. The method according to claim 1, wherein the pitch of the opaque pads is constant across the entire mask.

5. The method according to claim 1, wherein each of the opaque pads has a cross-section inscribed within a square, the dimensions of the side of the square for the opaque pads of the two regions being different.

6. The method according to claim 1, wherein the difference in the heights of the two pillars is in a range from 1 nm to a thickness of the layer.

7. The method according to claim 1, wherein the difference in the heights of the two pillars is in a range of 50 nm and 2,000 nm, inclusive.

8. The method according to claim 1, wherein the height of the protrusions is in the range from 0 nm to 200 nm.

9. The method according to claim 1, wherein the height of the protrusions is in the range of 40 nm and 100 nm, inclusive.

10. The method according to claim 8, wherein the height of the protrusions depends on a duration of the development of the resist layer.

11. The method according to claim 1, wherein the resist layer rests on a substrate, the method further comprising anisotropic etching of the resist layer and of the substrate, which results in a transferring of a shape of the pillars and of the protrusions into the substrate.

12. The method according to claim 1, wherein a top of each pillar has an area greater than 1 μm².

13. A structure, comprising:
a resist layer comprising:
at least two pillars of different heights and protrusions of nanometric heights at a top of each pillar, wherein the height of the protrusions is between 30 nm and 100 nm, inclusive; and
a total height of one of the pillars and the protrusions at the top of the one of the pillars is different from a total height of the other of the pillars and the protrusions at the top of the other of the pillars.

14. The structure according to claim 13, wherein the top of each pillar has an area greater than 1 μm².

15. The structure according to claim 13, further comprising a substrate under the resist layer, and the pillars being between the protrusions and the substrate.

16. The structure according to claim 13 wherein the height of the protrusions is between 40 nm and 100 nm, inclusive.

17. The structure according to claim 13, wherein each protrusion has a top, wherein the tops of the protrusions on one of the at least two pillars are in a first plane and wherein the tops of the protrusions on the other of the at least two pillars are in a second plane distant from the first plane.

18. A structure, comprising:
a layer comprising:
at least one first pillar with at least one first protrusion on the at least one first pillar; and
at least one second pillar with at least one second protrusion on the at least one second pillar, a first height from a top of the at least one first protrusion to a bottom of the at least one first pillar different from a second height from a top of the at least one second protrusion to a bottom of the at least one second pillar, and the at least one first protrusion and the at least one second protrusion having nanometric height.

19. The structure according to claim 18, wherein there are multiple first pillars arranged in an array on the at least one first pillar, and there are multiple second pillars arranged in an array on the at least one second pillar.

20. The structure according to claim 18, wherein a first radius of the at least one first protrusion at mid-height of the at least one first protrusion is different from a second radius of the at least one second protrusion at mid-height of the at least one second protrusion.
